(19) United States
(12) Patent Application Publication
(10) Pub. No.: US 2010/0308907 A1
(43) Pub. Date: Dec. 9, 2010

(54) Type of High-Performance DC Amplification Device for Bioelectrical Signal Collection

(75) Inventors: Xiaofei Xiang, Nanshan Shenzhen (CN); Xunqiao Hu, Nanshan Shenzhen (CN); Lingfeng Kong, Nanshan Shenzhen (CN); Sihai Qiu, Nanshan Shenzhen (CN)

Correspondence Address: GARCIA-ZAMOR INTELLECTUAL PROPERTY LAW;ATTN: RUY GARCIA-ZAMOR, 12960 LINDEN CHURCH ROAD, CLARKSVILLE, MD, 21029, US

(73) Assignee: Edan Instruments, Inc., Nanshan Shenzhen (CN)

(21) Appl. No.: 12/480,166

(22) Filed: Jun. 8, 2009

(51) Int. Cl. H03F 1/00

(52) U.S. Cl. 330/124 R

(57) ABSTRACT

This invention relates to a high-performance DC amplifying device for bioelectrical signal collection, including the sequentially linked input protective/filter circuit, input buffer circuit, instrumentation amplification circuit, RC low-pass filter circuit, analog-digital conversion and peripheral circuit and CPU, as described as below: the input protective/filter circuit collects the bioelectrical signal and sends such signal to the input buffer circuit and then allows it pass through the instrumentation amplification circuit, RC low-pass filter circuit and analog-digital conversion and peripheral circuit in order. For such device, CPU controls the operation of analog-digital conversion and peripheral circuit. This invention converts the impedance of bioelectrical signal firstly and then applies the common-mode signal rejection to the amplified signal, with the high-frequency noise filtered; such signal is treated for the secondary amplification by the single-ended-to-differential operational amplifier—the noise and common-mode rejection ratio and other indicators of such signal after analog-digital conversion reach a very high level and the baseline is very stable; the dynamic range of signal input is large and it is not saturated easily. With fewer parts needed, the reliability of such device is enhanced.

### TECHNICAL FIELD

This invention involves in the field of an electronic detection technology, specifically in the detection of the weak bioelectrical signal and particularly in the high-performance DC amplification device for bioelectrical signal collection.

### BACKGROUND ART

The current weak bioelectrical signal detection is conducted with the strong background interference and the patient's polarized voltage, in which the bioelectrical signal on the surface of human body is at the MV level only and the polarized voltage is often at hundreds of MV. Furthermore, the 50/60 HZ power interference from space coupling to human body may as high as dozens of volt and patient is a very complex signal source—its equivalent output impedance and polarized voltage are often in the changing status. It is hard to obtain the neat bioelectrical signal accurately and quickly. The more complicated AC amplification circuit structure is universally applied so far, including buffer, instrumentation amplification, time constant circuit, multistage low-pass filter, two-stage amplification, analog switch, differential level shift, analog-to-digital conversion and other multistage amplification circuit structures. With the blocking of capacitor, such amplification circuits belong to the AC amplifying devices. Whereas bioelectrical signal is very weak, the demand of analog-to-digital conversion and recording can be satisfied when such signal is amplified by hundredfolds. Since the electronic poles contact with human skin and there is the polarized voltage, the first-stage gain of the common amplifiers is smaller to avoid the saturation of amplifiers and it is necessary to re-amplify with the second-stage amplifier after isolating the polarized voltage by means of the resistance-capacitance circuit. When a patient is in the unstable case (e.g., muscle contraction, electrode shift, etc.), the lead will produce higher interference voltage due to the presence of time constant circuit—such interference voltage will cause saturation to the first-stage amplifier output and then charge the capacitor. If the said patient recovers the stable case (the patient's polarized voltage hits a smaller normal value) at this moment, a clinical baseline shift will occur due to the time difference between such recovery and the very long duration during which the blocking capacitor releases its electronic charges—within such time difference, no ECG signal collection can be done. Such AC amplifying devices have the following problems:
1. Small dynamic rang of signal; the circuits of AC amplifying device often have the gains from hundredfolds to thousand folds—it is supposed that the total gain is at 1000 folds as a typical value and the source voltage of amplification circuit is calculated at +5V, then the dynamic range is at ±5 mV only, and such dynamic range will lower if the non-rail-rail attribute, imbalance, temperature drift and other factors of general operational amplifier, whereas the ECG amplitude of clinical patients may completely exceed ±5 mVa, and such circuits will cause the cut-off distortion for those ECG signals with higher amplitude and cannot meet the demands of the practical clinical test therefore.
2. Amplifying circuit generally includes the buffer stage, amplification stage of Three OP AMP Instrumentation Amplifier, RC time constant circuit stage, low-pass filter circuit stage, main gain stage and other multiple links, with complex wiring, and each link will increase the noise—as a result, it is hard to control the noise level of the system and the equivalent input noise level is generally at more than 15 uVpp. Additionally, more parts are applied and the weak signal trace of printed circuit card is universally very long, allowing such devices are liable to the effects of the radiation sources of spatial interference and have the undesirable anti-interference capability.
3. With high gain of amplifier and small dynamic range of signal for such devices, a subtle signal disturbance (e.g., muscle contraction, electrode shift) will easily cause the saturation of amplifier in the clinical application. It will take a very long for the baseline to recover due to the effects of the time constant circuit and this means a fatal defect in the field of the clinical ECG detection—it is difficult for a doctor to bear the amplifier saturation and baseline drift problems arising from the baseline drift.
4. PACE pulse detection problem. Such problem is also cause by the attribute of AC structure. PACE signal may be very high (at 700 mVpp in the extreme case) and the small dynamic range of the AC amplification circuit will cause the output saturation of its operational amplifier and the baseline will produce a very big drift therefore plus the effects from the charging and discharging of the time constant circuit. Thus it is hard for the AC amplification structure to detect PACE signal effectively.
5. Losing the DC component of signal source and the AC signal close to the DC signal. Whereas the parameter of the RC time constant circuit is fixed (the typical value of time constant is 3.2 S), the AC signals less than 0.05 HZ will be lost by the AC amplification circuit and the low-frequency signal containing the important information of signal source cannot be reflected. With the exceptions and other effects with regard to ST section in the field of ECG detection, it is hard to provide the non-distorted accurate waveforms to doctors.
6. High source voltage is not conducive to low power consumption. Such AD amplification devices often apply the higher source voltage to ensure the dynamic range and gain and such practice is unfavorable to the control of power consumption of boards and cards and disagrees with the industrial development trend of low voltage and low power consumption.

### CONTENTS OF THE INVENTION

This invention aims to provide a type of high-performance DC amplification device for bioelectrical signal collection and such device can solve the existing technical problems effectively and also greatly simplify the design of bioelectrical front-end circuits, having a very high performance while maintaining a moderate production cost

This invention is made by means of the following technical solution:

A type of high-performance DC amplification device for bioelectrical signal collection, which is characterized in that such device includes: the sequentially linked input protective/filter circuit (10), input buffer circuit (20), instrumentation amplification circuit (30), RC low-pass filter circuit (40) and analog-digital conversion and peripheral circuit (50) and CPU (60), whereas the input protective/filter circuit (10) collects the bioelectrical signal and sends such signal to the input buffer circuit (20) and then allows it pass through the instrumentation amplification circuit (30), RC low-pass filter circuit(40) and analog-digital conversion and peripheral circuit (50) in order. For such device, CPU (60) controls the operation of analog-digital conversion and peripheral circuit (50). This invention converts the impedance of bioelectrical signal firstly and then applies the common-mode signal suppression to the amplified signal to filter the high-frequency noise; such signal is treated for the secondary amplification by the single-ended-to-differential operational amplifier and the analog-digital conversion is applied to the amplified bioelectrical signal to obtain the non-distorted bioelectrical signal.

The input protective/filter circuit (10) is composed of gas discharge tube, current-limiting resistor, filter capacitor and dual-diode—in which: two ends of the gas discharge tube are connected respectively with the lead input end and floating ground; one end of the current-limiting resistor is connected with the lead input end and the other end is connected with the inphase input end of the input buffer circuit (20); one end of the filter capacitor is connected with the inphase end of the input buffer circuit (20) and the other end is connected with the floating ground; the center tap end of the dual-diode is connected with the inphase end of the buffer amplifier and the other two ends are connected respectively with the positive and negative power supplies.

The input buffer circuit (20) is composed of a low-noise single-operational amplifier in the form of voltage follower, with its inphase end connected with the current-limiting resistor in the input protective/filter circuit (10) and its opposition phase is connected with the input end and also with the input stage of the instrumentation amplification circuit (30).

The inphase input ends of the instrumentation amplification circuit (30) are connected respectively with the buffer input ends of each branch; the input end of the instrumentation amplifier is connected with the RC low-pass filter circuit (40); the REF end of the instrumentation amplification circuit (30) is connected with the floating ground, and the instrumentation amplification circuit (30) transforms the inputted differential signal into the single-ended signal.

The RC low-pass filter circuit (40), with its first-order low-pass filter composed of a resistor and a capacitor, has its resistor end connected with the output end of the instrumentation amplifier and the other end connected with the filter capacitor, whereas the other end of the filter capacitor is connected with the floating ground and the common end of the filter capacitor and resistor is connected with the input end of the 8-channel data selector.

The analog-digital conversion and peripheral circuit (50) includes the analog-digital converter U20, in which the VREFN of the analog-digital converter U20 is connected with the AVSS pin of the negative power supply (See the output end of U19 for the voltage linking to VREFP), and the digital signal output end of the analog-digital converter U20 is connected with the data input interface of CPU.

The digital signal output end of the analog-digital converter is connected with the data input interface of the CPU (60); the input end of the analog switch U22 is connected with the output end of the RC low-pass filter circuit (40); the output end of the analog switch U22 is connected with the input end of the single-ended-to-differential operational amplifier U18; the control cable of the analog switch is connected with the I/O cable of the microprocessor U21. In the case that the signal's absolute voltage range is unchanged, U18 increases the signal's dynamic range by two folds—such case is conducive to increase of the system's resolution. After passing through the circuit U18, the signal is transformed into the differential signal from the singled-ended signal, and then sent to ADC for analog-digital conversion after passing through the first-level differential RC low-pass filter circuit. Controlled by the CPU program, ADS1258 U20 transforms the needed analog signal into 24-bit digital signal with the data entered in CPU through the SPI terminal. The CPU U21 communicates with ADS 1258 through the SPI terminal. After the further processing inside CPU, the transformed data will be sent to the host through the serial interface (or parallel interface, USB interface)—thus the DC amplification of ECG signal and high-speed data acquisition and processing have been finished.

The microprocessor's ports PA10/12, 16, 17, 18 and 30 act as the interfaces for communication with the analog-digital converter U20; the port PA0/PA1 acts as the USART interface for communication with the host and the port PB19 acts as the PWM output interface.

With the technical solution hereinabove, this invention has the following advantages:
1. High performance, noise and common-mod rejection ratio and other key indicators can reach a very level (anti-polarized voltage at ±600 mV, common-mode rejection ratio at 121 dB, noise at 12.5 uVpp) and the baseline is very stable;
2. DC amplification structure, without time constant circuit and quick output of bioelectrical signal;
3. Big dynamic range of signal input and uneasy saturation;
4. Less parts and high reliability;
5. Supporting the perfect PACE pulse detection.

This invention boasts the easy circuit structure, very high capability of bioelectrical signal acquisition, high circuit integration favorable to the miniaturization of boards and cards and remarkable economic and social benefit, which can be applied extensively to various bioelectrical detectors and detection systems for ECG, EEG and EMG (electromyography).

### DESCRIPTION OF FIGURES

FIG. 1 means the schematic diagram of operational principle of a circuit structure involved in this invention.

FIG. 2 means the schematic diagram of operational principle of another circuit structure involved in this invention.

### MODE OF CARRYING OUT THE INVENTION

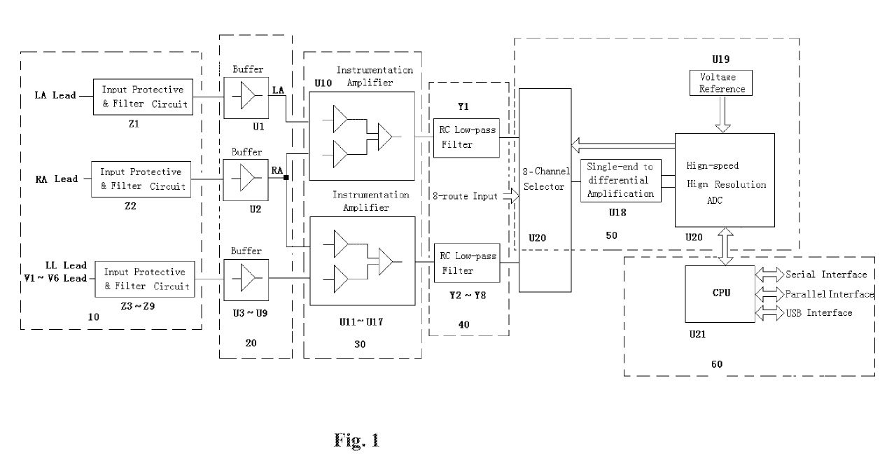

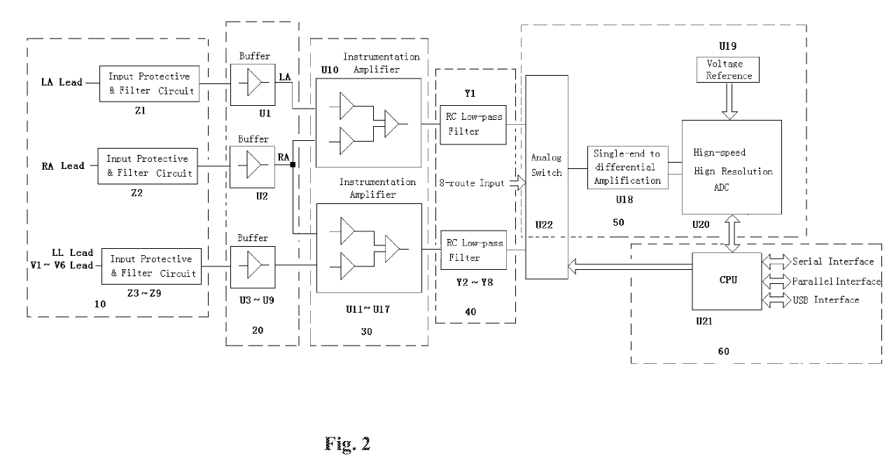

This invention is further described on the basis of the attached figures as below: Shown as FIG. 1 and FIG. 2, the present invention involves in a type of high-performance DC amplification device for bioelectrical signal collection, which includes the input protective/filter circuit (10), input buffer circuit (20), instrumentation amplification circuit (30), RC low-pass filter circuit (40) and analog-digital conversion and peripheral circuit (50) and CPU (60), whereas the input protective/filter circuit (10) collects the bioelectrical signal and sends such signal to the input buffer circuit (20) and then allows it pass through the instrumentation amplification circuit (30), RC low-pass filter circuit (40) and analog-digital conversion and peripheral circuit (50) in order. The CPU (60) controls the operation of analog-digital conversion and peripheral circuit (50).

The input protective/filter circuit (10) has nine routes from Z1 to Z9 and each route is composed of a gas discharge tube, a current-limiting resistor, a filter capacitor and a dual-diode. One end of the current-limiting resistor is connected with the lead input end and the other end is connected with the inphase input end of the input buffer U1; one end of the filter capacitor is connected with the inphase end of the input buffer U1 and the other end is connected with the floating ground; the center tap end of the dual-diode is connected with the inphase end of the buffer amplifier U1 and the other two ends are connected respectively with the positive and negative power supplies.

Whereas the bioelectrical signal on the human body surface is very weak, and the contact resistance from bioelectrical signal lead and human body and internal resistance of signal source are very high, it is necessary to set up the input buffer circuit (20) to obtain the ECG signal effectively—such circuit has 9 routes and each route is composed of a low-noise single operational amplifier featuring very low noise and bias current for meeting the demand of low-noise amplification and impedance conversion. This invention applies CMOS input-level operational amplifier to the input buffer circuit (20), which are connected in the form of voltage follower so as to greatly increase the input impedance of ECG detection circuit—with the DC input impedance increased as high as at more than 100 Gohm, and to obtain the bioelectrical signal furthest.

The instrumentation amplifying circuit (30) has 8 routes and the buffered bioelectrical signal has its common-mode interference suppressed greatly after passing through the instrument amplifier (30). The opposition phase input ends of each instrumentation amplifier are connected with the buffer U2′ output end of the RA branch, and the inphase input ends of each instrumentation amplifier are connected with respectively with the buffer output end of its branch The output end VOUT of the instrumentation amplifier is connected with the resistor of the RC filtering network and the REF end of the instrumentation amplifier is connected with the floating ground—such instrumentation amplifier is the first gain stage and has less gain, ensuring the acquisition of polarized voltage and preventing saturation. The rejection of common-mode signal (e.g. 50/60 HZ power interference) is completed mostly at this stage. The instrumentation amplifier transformers the entered differential signal into the single-ended signal and then sends to the RC filtering stage for further processing. This embodiment applies AD8221 single instrumentation amplifier, in which the low-frequency (less than 1 KHz) common-mode signal can be suppressed by 100 dB and above, with 70 dB of suppression capability at the medium- and high-frequency at 100 KHZ, whereas most of instrumentation amplifiers have only 40 dB of suppression capability at such frequency point. After the processing in this circuit, the neat ECG signals can be obtained.

The RC low-pass filter circuit (40) has 8 routes and each together with a resistor and a capacitor constitute a first-order low-pass filtering and the −3 dB cut-off frequency of such low-pass filtering at this stage is configured at 450 HZ. After the low-pass filtering, bioelectrical signal are transmitted to the 8-channel data selector.

The analog-digital conversion and peripheral circuit (50) is composed of the 8-channel selector (or analog switch), singled-ended-to-differential amplification circuit U18, voltage reference U19, high-speed high resolution ADC. In the embodiment as shown in FIG. 1, the analog-digital converter U20 has been integrated with the 8-channel selector. The analog-digital converter has the high-speed Delta-Sigma structure ADC and the sampling rate of multichannel switching can reach 23.7 Ksps—such rate can meet the demand of multichannel bioelectrical signal collection, with the accuracy at 24 bit and the system's noise level decreased significantly. Its equivalent input noise is at 12 uVrms only and such level can ensure the system's equivalent noise level to be less than 12.5 uVpp. After passing through the data selector, the ECG signals are sent to the single-ended-to-differential amplification circuit U18 for further processing, and U18 will increase the signal's dynamic range by two folds without change of the signal's absolute voltage range—such case is helpful to increasing the system's resolution. After passing through U18, the signal is transformed into the differential signal from the single-ended signal and then sent to ADC for analog-digital conversion after passing through the first-level antialiasing differential RC low-pass filter circuit. Controlled by the CPU program, ADS1258 U20 transforms the needed analog signal into 24-bit digital signal with the data entered in CPU through the SPI terminal. After the further processing inside CPU, the transformed data will be sent to the host through the serial interface (or parallel interface, USB interface)—thus the DC amplification of ECG signal and high-speed data acquisition and processing have been finished.

As shown in FIG. 2, the digital signal output end of the analog-digital converter is connected with the data input interface of the CPU (60); the input end of the analog switch U22 is connected with the output end of the RC low-pass filter circuit (40); the output end of the analog switch U22 is connected with the input end of the single-ended-to-differential operational amplifier U18; the control cable of the analog switch is connected with the I/O cable of the microprocessor U21. Whereas this invention has few links of analogue gain and the operational amplifier and instrumentation amplifier are low-noise parts, the simple first-order RC low-pass filter can be applied to the analog channel. The 8-channel selector select the filtered signals and send them to the singled-ended-to-differential circuit of U20 for the second-stage gain and amplification (the channel selector is integrated by ADS1258 and the channels to be scanned can be selected by configuring BITS CHID [4:0]); the amplified signals are the differential signals—the dynamic range is increased by one fold after such amplification, and the ADC applies the analog-digital conversion.

The CPU (60) includes a microcontroller U21 that receives the user's instructions through serial interface, parallel interface or USB interface and controls the analog-digital conversion and the process of data acquisition. After the beginning of data acquisition, the microcontroller U21 transmits the control instructions of data acquisition to the 8-channel selector U20 through the SPI terminal to select the corresponding channel and to start the analog-digital conversion. The microcontroller U21 extract the converted data through the SPI terminal and save such data in the RAM and the channel selector U21 select the next channel switch to start the analog-digital conversion. The present invention applies the impedance conversion to bioelectrical signal firstly and then suppresses the common-mode signals after the amplification of bioelectrical signal; the singled-ended-to-differential amplifiers carries out the secondary amplification for bioelectrical signal after the filtering network filters the high-frequency noise, and then the analog-digital conversion is conducted for the amplified bioelectrical signal to obtain the non-distorted bioelectrical signal.

1. A type of high-performance DC amplification device for bioelectrical signal collection, which is characterized in that such device includes: the sequentially linked input protective/filter circuit (10), input buffer circuit (20), instrumentation amplification circuit (30), RC low-pass filter circuit (40) and analog-digital conversion and peripheral circuit (50) and CPU (60), whereas the input protective/filter circuit (10) collects the bioelectrical signal and sends such signal to the input buffer circuit (20) and then allows it pass through the instrumentation amplification circuit (30), RC low-pass filter circuit(40) and analog-digital conversion and peripheral circuit (50) in order. As a result, the non-distorted bioelectrical signal is outputted when CPU (60) controls the operation of analog-digital conversion and peripheral circuit (50).

2. A type of high-performance DC amplification device for bioelectrical signal collection according to claim 1, which is characterized in that the input protective/filter circuit (10) is composed of gas discharge tube, current-limiting resistor, filter capacitor and dual-diode—in which: two ends of the gas discharge tube are connected respectively with the lead input end and floating ground; one end of the current-limiting resistor is connected with the lead input end and the other end is connected with the inphase input end of the input buffer circuit (20); one end of the filter capacitor is connected with the inphase end of the input buffer circuit (20) and the other end is connected with the floating ground; the center tap end of the dual-diode is connected with the inphase input end of the input buffer circuit (20) and the other two ends are connected respectively with the positive and negative power supplies.

3. A type of high-performance DC amplification device for bioelectrical signal collection according to claim 1, which is characterized in that the input buffer circuit (20) is composed of a low-noise single-operational amplifier in the form of voltage follower, with its inphase end connected with the current-limiting resistor in the input protective/filter circuit (10) and its opposition phase is connected with the input end and also with the input stage of the instrumentation amplification circuit (30).

4. A type of high-performance DC amplification device for bioelectrical signal collection according to claim 1, which is characterized in that the inphase input ends of the instrumentation amplification circuit (30) are connected respectively with the buffer input ends of each branch; the input end of the instrumentation amplifier is connected with the RC low-pass filter circuit (40); the REF end of the instrumentation amplification circuit (30) is connected with the floating ground, and the instrumentation amplification circuit (30) transforms the inputted differential signal into the single-ended signal.

5. A type of high-performance DC amplification device for bioelectrical signal collection according to claim 1, which is characterized in that the RC low-pass filter circuit (40), with its first-order low-pass filter composed of a resistor and a capacitor, has its resistor end connected with the output end of the instrumentation amplifier and the other end connected with the filter capacitor, whereas the other end of the filter capacitor is connected with the floating ground and the common end of the filter capacitor and resistor is connected with the input end of the 8-channel data selector.

6. A type of high-performance DC amplification device for bioelectrical signal collection according to claim 1, which is characterized in that the analog-digital conversion and peripheral circuit (50) includes the analog-digital converter U20, in which the VREFN of the analog-digital converter U20 is connected with the AVSS pin of the negative power supply, VREFP is connected with the output end of the voltage reference U19 and the digital signal output end of the analog-digital converter U20 is connected with the data input interface of the CPU (60).

7. A type of high-performance DC amplification device for bioelectrical signal collection according to claim 1, which is characterized in that the input end of the analog switch in the analog-digital conversion and peripheral circuit (50) is connected with the output end of the RC low-pass filter circuit(40) and the output end of such analog switch is connected with the input end of the single-ended-to-differential operational amplifier, and that the control cable of the analog switch is connected with the I/O cable of the microprocessor.

8. A type of high-performance DC amplification device for bioelectrical signal collection according to claim 1, which is characterized in that the CPU (60) includes a microprocessor and peripheral circuit, in which the microprocessor's ports PA10/12, 16, 17, 18 and 30 act as the interfaces for communication with the analog-digital converter U20, the port PA0/PA1 acts as the USART interface for communication with the host and the port PB19 acts as the PWM output interface.
